(19) United States
(12) Patent Application Publication
(10) Pub. No.: US 2025/0324564 A1
(43) Pub. Date: Oct. 16, 2025

(54) GATE STRUCTURE DISPOSED BETWEEN FIN STRUCTURES TO DECREASE LEAKAGE IN GAIN CELL RANDOM ACCESS MEMORY (GCRAM)

(71) Applicant: Taiwan Semiconductor Manufacturing Company, Ltd., Hsinchu (TW)

(72) Inventors: Wei Ting Hsieh, Hsinchu (TW); Kuen-Yi Chen, Hsinchu City (TW); Yi Ching Ong, Hsinchu (TW); Yu-Wei Ting, Taipei City (TW); Kuo-Ching Huang, Hsinchu City (TW)

(21) Appl. No.: 19/250,144

(22) Filed: Jun. 26, 2025

Related U.S. Application Data
(63) Continuation of application No. 18/619,632, filed on Mar. 28, 2024.
(60) Provisional application No. 63/600,064, filed on Nov. 17, 2023.

(51) Int. Cl. H10B 12/00

(52) U.S. Cl. CPC H10B 12/00

(57) ABSTRACT

Various embodiments of the present application are directed towards an integrated chip. The integrated chip includes a first fin structure and a second fin structure disposed on a base region of a substrate. A first source/drain region is disposed on the first fin structure. A second source/drain region is disposed on the second fin structure. A gate structure overlies the base region of the substrate and is spaced laterally between the first and second fin structures. A bottom surface of the gate structure is disposed below bottoms of the first and second source/drain regions.

### REFERENCE TO RELATED APPLICATIONS

This application is a Continuation of U.S. application Ser. No. 18/619,632, filed on Mar. 28, 2024, which claims the benefit of U.S. Provisional Application No. 63/600,064, filed on Nov. 17, 2023. The contents of the above-referenced patent applications are hereby incorporated by reference in their entirety.

### BACKGROUND

Many modern electronic devices contain electronic memory configured to store data. As technology advances at a rapid pace, engineers work to make memory devices smaller, yet more complex to improve and develop electronic devices that are more efficient, more reliable, and have more capabilities. Electronic memory may be volatile memory or non-volatile memory. Volatile memory stores data while it is powered, while non-volatile memory is able to store data when power is removed. Gain cell random-access memory (GCRAM) is one promising candidate for a next generation volatile memory technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a diagram of some embodiments of an integrated chip including a GCRAM cell having a transistor with low leakage current.

FIG. 2 illustrates a circuit diagram of some embodiments of the GCRAM cell of FIG. 1.

FIGS. 3A-3C illustrate various views of some embodiments of an integrated chip that includes a plurality of GCRAM cells that respectively have a transistor with low leakage current.

FIGS. 4A-4C illustrate various views of some embodiments of an integrated chip corresponding to some other embodiments of the integrated chip of FIGS. 3A-3C.

FIGS. 5A-5C illustrate cross-sectional views of some embodiments of an integrated chip that includes a plurality of GCRAM cells that respectively have a transistor with low leakage current.

FIG. 6 illustrates a cross-sectional view of some embodiments of an integrated chip that includes a GCRAM cell having a write transistor and a read transistor disposed on a substrate.

FIG. 7 illustrates a circuit diagram of some embodiments of an integrated chip having a GCRAM cell comprising a write transistor, a first read transistor, and a second read transistor.

FIG. 8 illustrates a circuit diagram of some embodiments of an integrated chip comprising a plurality of GCRAM cells disposed in a memory array.

FIG. 9 illustrates a graph comprising a series of voltage curves of some embodiments of GCRAM cells during different operation conditions.

FIGS. 10-21 illustrate cross-sectional views of some embodiments of a method of forming an integrated chip that includes a GCRAM cell having a transistor with low leakage current.

FIGS. 22-26 illustrate cross-sectional views of some other embodiments of a method for forming an integrated chip that includes a GCRAM cell having a transistor with low leakage current.

FIG. 27 illustrates a flow diagram of some embodiments of a method of forming an integrated chip that includes a GCRAM cell having a transistor with low leakage current.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated chip may comprise a plurality of memory cells disposed over a substrate. A memory device (e.g., a cache memory device) may include memory cells (e.g., volatile memory cells) with high-speed data access and low latency for high-speed processors, where the memory cells may respond to a processor request in a few nanoseconds or less. Over the past couple of decades, static random-access memory (SRAM) cells have been traditionally utilized in memory devices (e.g., a cache memory) of integrated chips that call for low latency and high-speed data access. SRAM cells are advantageous because of their high-speed data access and low latency. In addition, SRAM cells may not utilize refresh operations. However, SRAM cells generally each comprise six or more functional elements (e.g., at least six transistors), may have low stability (e.g., due to electrical properties being affected by environmental conditions), and may have high power consumption. Further, a cache memory device may occupy a large area of the integrated chip (e.g., occupies about 50% of the substrate's overall area), where the six or more functional elements of each SRAM cell decreases a bit density of the integrated chip.

Gain cell random-access memory (GCRAM) cells have increased in popularity over the last decade as an alternative to SRAM cells due to their higher stability, lower power consumption, and lower number of functional elements compared to SRAM cells. For example, GCRAM cells may have three or four functional elements (e.g., compared to the six or more functional elements of an SRAM cell) such that the GCRAM cells have a small size that increases the bit density of the integrated chip. Further, the lower number of functional elements increases a stability and decreases power consumption of the GCRAM cells.

An integrated chip may include a plurality of GCRAM cells disposed in a memory array comprising rows and columns, where each GCRAM cell is addressable. However, a challenge with using GCRAM cells is that GCRAM cells may have short data retention times that result in the use of frequent refresh operations on the plurality of GCRAM cells. The short data retention time of the GCRAM cells may be due to leakage in one or more of the functional elements. For example, a GCRAM cell comprises a write transistor having a pair of source/drain regions coupled between a write bit line and a storage node, a capacitor coupled to the storage node, and a read transistor having a gate electrode coupled to the storage node. The GCRAM cell is configured to operate in a standby mode when data is not being read from or written to the GCRAM cell (e.g., while reading and/or writing to other GCRAM cells in the memory array). The write transistor may have a high leakage current due to, for example, subthreshold leakage, gate-induced drain leakage (GIDL), and/or junction leakage in the write transistor. The high leakage current of the write transistor may cause a data state of the GCRAM cell to change while in the standby mode, thereby decreasing a data retention time of the GCRAM cell. As a result, refresh operations are frequently performed on the GCRAM cells to facilitate the GCRAM cells maintaining accurate data states. The frequent refresh operations increases power consumption of the integrated chip and increases a complexity and/or number of devices in support circuitry configured to perform the frequent refresh operations.

Further, sizes of the GCRAM cells may be scaled to increase the bit density of the integrated chip. However, the scaling of sizes may further decrease performance of the GCRAM cells. For example, the write transistor includes a channel region defined along a horizontal surface of the substrate between the pair of source/drain regions of the write transistor. A length of the channel region is proportionate to a length of the horizontal surface of the substrate that extends between the pair of source/drain regions (e.g., the length of the channel region is approximately equal to a length of a gate electrode of the write transistor). Reducing the length of the horizontal surface of the substrate between the source/drain regions facilitates decreasing a lateral footprint of each GCRAM cell and increases bit density. Nonetheless, this reduces the length of the channel region such that the write transistor suffers from performance issues that are referred to as “short channel effects.” The short channel effects causes increased leakage current in the write transistor, thereby further decreasing the data retention time of the GCRAM cells and increasing the frequency of refresh operations. Accordingly, sizes of the GCRAM cells may not be scaled down without reducing performance of the GCRAM cells.

Accordingly, various embodiments of the present application are directed towards a GCRAM cell including a write transistor with a gate structure disposed between first and second fin structures that decreases leakage current. The first fin structure and the second fin structure extend vertically upward from a base region of a substrate. The gate structure is spaced laterally between the first and second fin structure. The write transistor further includes a first source/drain region disposed on the first fin structure and a second source/drain region disposed on the second fin structure. A channel region of the write transistor extends along sidewalls of the first and second fin structures and a bottom surface of the gate structure between the first and second fin structures. As a result, a length of the channel region is increased while maintaining or decreasing a lateral distance between the first and second source/drain regions. In such instances, portions of the channel region extending vertically along the first and second fin structures adds to the length of the channel region without increasing the lateral distance between the first and second source/drain regions. The increased length of the channel region reduces issues related to subthreshold leakage, GIDL, and/or junction leakage, thereby decreasing an overall leakage current in the write transistor. Accordingly, a data retention time of the GCRAM cell is increased, thereby decreasing a frequency of refresh operations performed on the GCRAM cell and decreasing a complexity and/or number of devices in support circuitry configured to perform the refresh operations. Further, increasing the length of the channel region while decreasing the lateral distance between the first and second source/drain regions facilitates scaling a size of the GCRAM cell while increasing the performance of the GCRAM cell.

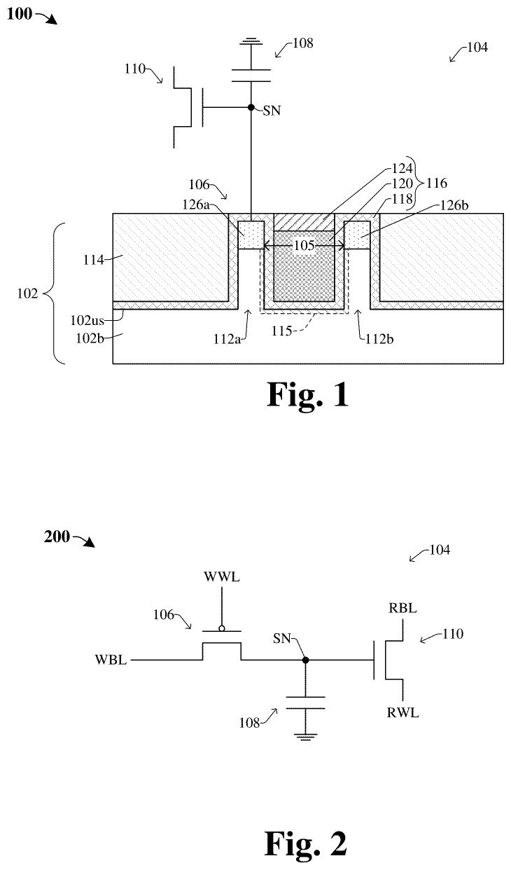

FIG. 1 illustrates a diagram 100 of some embodiments of an integrated chip including a GCRAM cell having a transistor with low leakage current.

The integrated chip includes a GCRAM cell 104 disposed on and/or over a substrate 102. In some embodiments, the GCRAM cell 104 includes a plurality of functional elements that comprise a write transistor 106, a capacitor 108, and a read transistor 110. The GCRAM cell 104 may, for example, be referred to as a two-transistor one-capacitor (2T1C) memory cell, an embedded memory cell, or the like. The substrate 102 comprises a base region 102b having an upper surface 102us. The write transistor 106 includes a first fin structure 112a and a second fin structure 112b extending from the base region 102b of the substrate 102. In various embodiments, the first and second fin structures 112a, 112b are portions of the substrate 102 that continuously extend from the upper surface 102us of the base region 102b.

The write transistor 106 further includes a gate structure 116 disposed between the first fin structure 112a and the second fin structure 112b, a pair of source/drain regions 126a, 126b disposed on the first and second fin structures 112a, 112b, and a channel region 115 disposed in the substrate 102 between the first and second source/drain regions 126a, 126b. Source/drain region(s) may refer to a source or a drain, individually or collectively dependent upon the context. The gate structure 116 includes a gate dielectric layer 118, a gate electrode 120, and a capping layer 124 over the gate electrode 120. In some embodiments, the gate dielectric layer 118 extends along opposing sidewalls of both the first and second fin structures 112a, 112b and over the upper surface 102us. The gate dielectric layer 118 is disposed between the gate electrode 120 and the first fin structure 112a, the second fin structure 112b, and the base region 102b. Further, an isolation structure 114 is disposed over the base region 102b of the substrate 102 on opposing sides of the first and second fin structures 112a, 112b.

The GCRAM cell 104 comprises a storage node SN electrically coupled to the first source/drain region 126a of the write transistor 106. The capacitor 108 is electrically coupled between the storage node SN and a reference voltage (e.g., ground). In various embodiments, a first electrode of the capacitor 108 is electrically coupled to the storage node SN and a second electrode of the capacitor 108 is electrically coupled to the reference voltage. A gate electrode of the read transistor 110 is coupled to the storage node SN.

During operation of the GCRAM cell 104, the gate electrode 120 of the write transistor 106 is selectively biased to vary a conductivity of the channel region 115. In some embodiments, during a set operation the write transistor 106 is configured to inject charge into the storage node SN such that the storage node SN is in a logical “1” state. In such embodiments, the write transistor 106 increases charge at the capacitor 108 and/or at a gate dielectric of the read transistor 110. In further embodiments, during a reset operation the write transistor is configured to remove charge from the storage node SN such that the storage node SN is in a logical “0” state. In such embodiments, the write transistor 106 decreases charge at the capacitor 108 and/or at the gate dielectric of the read transistor. Thus, in some embodiments, a data state of the GCRAM cell 104 at the storage node SN is defined at least in part by the charge at the capacitor 108 and/or the gate dielectric of the read transistor 110. Further, the read transistor 110 is configured to perform non-destructive read operations on the GCRAM cell 104.

The channel region 115 extends along the gate structure 116 between the first source/drain region 126a and the second source/drain region 126b. For example, the channel region 115 extends vertically along a sidewall of the first fin structure 112a abutting a first side of the gate structure 116, extends horizontally along the upper surface of 102us of the base region 102b directly below the gate structure 116 and between the first and second fin structures 112a, 112b, and extends vertically along a sidewall of the second fin structure 112b abutting a second side of the gate structure 116. Because the channel region 115 extends vertically along both the first and second fin structures 112a, 112b and horizontally along the upper surface 102us, a length (not label) of the channel region 115 is increased and is greater than a lateral distance 105 between the pair of source/drain regions 126a, 126b. As a result, leakage current in the write transistor 106 is decreased.

In various embodiments, the GCRAM cell 104 is configured to be in a standby mode when read and/or write operations are not being performed on the GCRAM cell 104. For instance, the GCRAM cell 104 may be in the standby mode when read or write operations are performed on other GCRAM cells (not shown) in the integrated chip. In some embodiments, in the standby mode, the write transistor 106 is in an off state, such that the channel region 115 is configured to have a low conductivity that electrically isolates the second source/drain region 126b from the storage node SN. However, leakage may occur between the write transistor 106 and the storage node SN during the standby mode, such that the voltage at the storage node SN changes during the standby mode. By virtue of the channel region 115 of the write transistor 106 being relatively long, leakage current from the write transistor 106 while in the standby mode is decreased. For example, the relatively long channel region 115 decreases subthreshold leakage, GIDL, and/or junction leakage in the write transistor 106, thereby decreasing overall leakage current in the GCRAM cell 104. As a result, the voltage at the storage node SN while in the standby mode changes more slowly such that the GCRAM cell 104 has an increased data retention time. This decreases a frequency in which refresh operations are performed on the GCRAM cell 104, thereby decreasing power consumption and decreasing a complexity and/or number of devices in support circuitry configured to perform the refresh operations.

In addition, because the gate electrode 120 is disposed between the first and second fin structures 112, 112b, the length of the channel region 115 is increased while the lateral distance 105 between the pair of source/drain regions 126a, 126b may be decreased. As a result, the performance of the write transistor 106 is increased while decreasing the lateral footprint of the GCRAM cell 104. Accordingly, a number of GCRAM cells disposed over the substrate 102 may be increased and/or an area of a memory device (e.g., a cache memory device) over the substrate 102 is reduced. For example, an area of the integrated chip dedicated to the memory device may be less than 25% of an overall area of the substrate 102. Therefore, a bit density and/or device density of the integrated chip may be increased while increasing the performance of the GCRAM cells.

While the foregoing discussion describes the write transistor 106 being implemented in a GCRAM cell, this is a non-limiting example and the write transistor 106 is not restricted to being used in a GCRAM cell. In other embodiments, the write transistor 106, with the relatively long channel region 115, may be used in other electronic applications that benefit from low leakage current and a reduced lateral footprint.

FIG. 2 illustrates a circuit diagram of some embodiments of the GCRAM cell 104 of FIG. 1. The GCRAM cell 104 comprises a write transistor 106, a capacitor 108, and a read transistor 110.

A gate electrode (e.g., 120 of FIG. 1) of the write transistor 106 is electrically coupled to a write word line WWL. Source/drain regions (e.g., 126a-b of FIG. 1) of the write transistor 106 are electrically coupled between a write bit line WBL and a storage node SN of the GCRAM cell 104. For example, a first source/drain region (e.g., 126a of FIG. 1) of the write transistor 106 is directly electrically coupled to the storage node SN and a second source/drain region (e.g., 126b of FIG. 1) of the write transistor 106 is directly electrically coupled to the write bit line WBL. The capacitor 108 is coupled between the storage node SN and a reference voltage (e.g., ground). A gate electrode of the read transistor 110 is electrically coupled to the storage node SN. Further, source/drain regions of the read transistor 110 are coupled between a read word line RWL and a read bit line RBL. For example, a first source/drain region of the read transistor 110 is coupled to the read word line RWL and a second source/drain region of the read transistor 110 is coupled to the read bit line RBL. In various embodiments, the GCRAM cell 104 is configured to store a data state at the storage node SN as described above in FIG. 1.

In some embodiments, after performing a write operation on the GCRAM cell 104, the GCRAM cell 104 may be held in a standby mode (e.g., while performing read and/or write operations on other GCRAM cells (not shown)). In various embodiments, while in the standby mode the write bit line WBL and the write word line WWL are suitable biased such that a channel region (e.g., 115 of FIG. 1) of the write transistor 106 is in a low conductivity state (i.e., the write transistor 106 is in an off state). However, as discussed above, the data state at the storage node SN may be prone to changing while the GCRAM cell 104 is in the standby mode due to leakage current in the write transistor 106. Accordingly, support circuitry (not shown) is configured to perform refresh operations on the GCRAM cell 104 to refresh the data state at the storage node SN to an appropriate value. For instance, the refresh operation sets the GCRAM cell 104 back to the data state defined in a last write operation performed on the GCRAM cell 104. By virtue of the write transistor 106 having a relatively long channel region (e.g., the length of the channel region is greater than a lateral distance between the source/drain regions of the write transistor 106), leakage current in the write transistor 106 is significantly reduced. As a result, the GCRAM cell 104 may retain an accurate data state for a longer time compared to other embodiments in which the channel region of the write transistor is relatively short (e.g., the length of the channel region is approximately equal to a lateral distance between the source/drain regions of the write transistor 106). Thus, a data retention time of the GCRAM cell 104 is increased and a frequency of the refresh operations is decreased, thereby decreasing a power consumption of the GCRAM cell 104 and increasing an overall performance of the GCRAM cell 104.

The write transistor 106 may, for example, be configured as illustrated and/or described in FIG. 1. In various embodiments, the write transistor 106 is configured as a p-type transistor and the read transistor 110 is configured as an n-type transistor or vice versa. In yet further embodiments, the write transistor 106 and the read transistor 110 may each be configured as a p-type transistor or an n-type transistor. The read transistor 110 may, for example, be configured as a planar metal-oxide-semiconductor (MOS) field-effect transistor (FET) (MOSFET), a fin FET (FinFET), a gate-all-around (GAA) FET (GAAFET), a nanowire FET, a nanosheet FET, or some other type of semiconductor device and/or transistor.

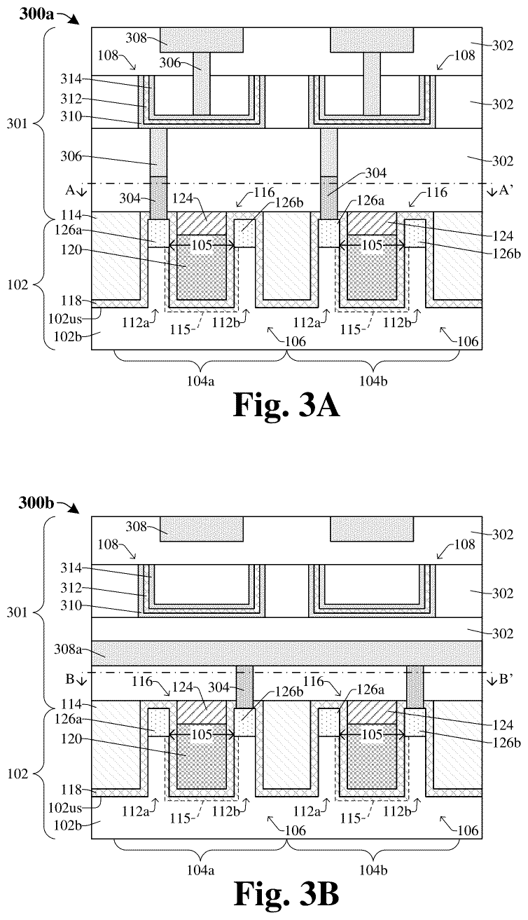

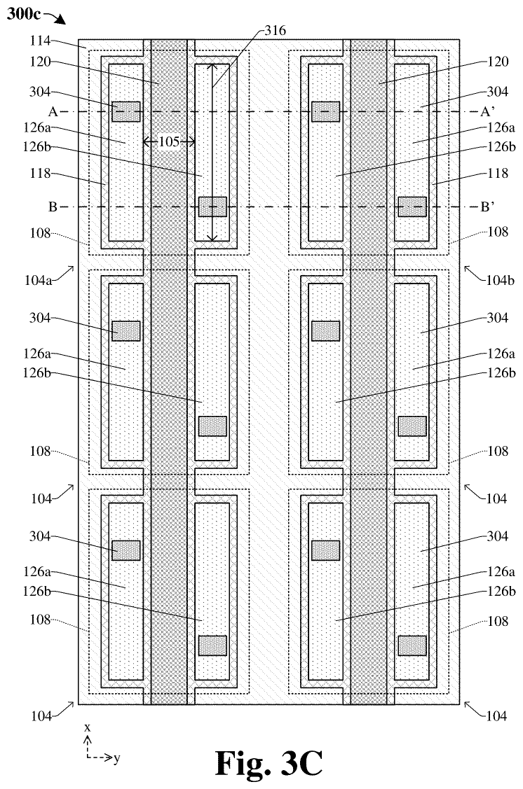

FIGS. 3A-3C illustrate various views of some embodiments of an integrated chip that include a plurality of GCRAM cells that respectively have a transistor with low leakage current. FIG. 3C illustrates a top view 300c of some embodiments of the integrated chip. FIG. 3A illustrates a cross-sectional view 300a of some embodiments of the integrated chip taken along the line A-A′ of FIG. 3C. FIG. 3B illustrates a cross-sectional view 300b of some embodiments of the integrated chip taken along the line B-B of FIG. 3C. It will be appreciated that structures (e.g., a dielectric layer 302 and/or a capping layer 124) from the cross-sectional views 300a and 300b of FIGS. 3A-3B may be omitted from the top view 300c of FIG. 3C for ease of illustration.

As shown in the top view 300c of FIG. 3C, the integrated chip comprises a plurality of GCRAM cells 104 that are arranged in a memory array having a plurality of rows and a plurality of columns. The GCRAM cell 104 comprises a first GCRAM cell 104a disposed in a first column of the plurality of columns and a second GCRAM cell 104b disposed in a second column of the plurality of columns. In various embodiments, GCRAM cells 104 disposed in a same column share a gate electrode 120 that continuously extends along a first direction (e.g., along the x-axis) across the GCRAM cells 104 in the same column.

As shown in the cross-sectional views 300a and 300b of FIGS. 3A and 3B, the integrated chip comprises a substrate 102. The substrate 102 may, for example, be or comprise a bulk substrate (e.g., bulk silicon), a silicon-on-insulator (SOI) substrate, germanium, gallium, one or more epitaxial layers (e.g., epitaxial silicon), some other suitable substrate material, or the like. Further, the substrate 102 includes a base region 102b that has an upper surface 102us. An interconnect structure 301 overlies the substrate 102.

The plurality of GCRAM cells 104 are disposed on the substrate 102. The GCRAM cells 104 each comprise a write transistor 106, a capacitor 108, and a read transistor (not shown). In various embodiments, the read transistor (not shown) is configured as illustrated and/or described in FIG. 1 or 2 and is disposed in a region of the substrate 102 laterally offset from the write transistor 106 (e.g., as illustrated and/or described in FIG. 6). Further, the first GCRAM cell 104a is laterally offset from the second GCRAM cell 104b by a non-zero distance. The write transistor 106 comprises first and second fin structures 112a, 112b, a gate structure 116 disposed between the first and second fin structures 112a, 112b, first and second source/drain regions 126a, 126b on the first and second fin structures 112a, 112b, and a channel region 115 extending between the first and second source/drain regions 126a, 126b. The gate structure 116 includes a gate dielectric layer 118, a gate electrode 120, and a capping layer 124.

The first and second fin structures 112a, 112b continuously vertically extend upward from the base region 102b of the substrate 102. In various embodiments, the first and second fin structures 112a, 112b are part of the substrate 102. The first and second fin structures 112a, 112b may, for example, be or comprise a same material (e.g., silicon) as the base region 102b of the substrate 102. In some embodiments, the first and second fin structures 112a, 112b are elongated in a first direction (e.g., along the x-axis of FIG. 3C) that extends parallel to elongated sidewalls of the gate electrode 120. The first and second source/drain regions 126a, 126b are disposed on tops of the first and second fin structures 112a, 112b and on opposing sides of the gate electrode 120. The channel region 115 extends vertically along the first and second fin structures 112a, 112b and horizontal along the upper surface 102us of the base region 102b directly under the gate electrode 120. In some embodiments, the first and second source/drain regions 126a, 126b are doped regions of the first and second fin structures 112a, 112b and/or comprise doped epitaxial silicon.

The gate dielectric layer 118 overlies the base region 102b of the substrate 102 and lines sidewalls of the first and second fin structures 112a, 112b. In some embodiments, the gate dielectric layer 118 extends along tops of the first and second source/drain regions 126a, 126b. The gate dielectric layer 118 separates the gate electrode 120 from the first and second fin structures 112a, 112b and the base region 102b. The gate electrode 120 is recessed below tops of the first and second fin structures 112a, 112b. In various embodiments, the gate electrode 120 is configured as a corresponding write word line (e.g., WWL of FIG. 2). The capping layer 124 overlies the gate electrode 120. In some embodiments, the capping layer 124 is configured to protect the gate electrode 120 and/or to prevent shorting between the gate electrode 120 and the first and second source/drain regions 126a, 126b. In further embodiments, a top surface of the capping layer 124 is coplanar with a top surface of the gate dielectric layer 118.

The gate electrode 120 may, for example, be or comprise doped polysilicon (e.g., n-doped polysilicon, p-doped polysilicon, etc.), one or more metals such as titanium, aluminum, titanium nitride, tantalum nitride, some other conductive material, or any combination of the foregoing. The gate dielectric layer 118 may, for example, be or comprise silicon dioxide, hafnium oxide, aluminum oxide, some other dielectric material, or any combination of the foregoing. The capping layer 124 may, for example, be or comprise silicon nitride, silicon dioxide, aluminum oxide, some other dielectric material, or any combination of the foregoing.

An isolation structure 114 overlies the base region 102b of the substrate 102. The isolation structure 114 may be configured as a shallow trench isolation (STI) structure and is configured to electrically isolate adjacent GCRAM cells from one another. The isolation structure 114 may, for example, be or comprise silicon dioxide, silicon nitride, silicon carbide, some other dielectric material, or any combination of the foregoing. In some embodiments, a top surface of the isolation structure 114 is coplanar with the top surface of the gate dielectric layer 118. In various embodiments, a height of the isolation structure 114 is greater than height of the gate electrode 120.

An interconnect structure 301 overlies the substrate 102. The interconnect structure 301 comprises a plurality of conductive structures disposed in a plurality of dielectric layers 302. The plurality of conductive structures include a plurality of conductive contacts 304, a plurality of conductive vias 306, and a plurality of conductive wires 308. The plurality of conductive structures are configured to electrically couple the GCRAM cells 104 to one another and/or to other semiconductor devices (not shown). In various embodiments, the plurality of conductive wires 308 comprises one or more first conductive wires 308a that may each be configured as a global word bit line connecting multiple second source/drain regions 126b of GCRAM cells 104 together. In such embodiments, the one or more first conductive wires 308a are elongated in a direction perpendicular to a direction the gate electrodes 120 are elongated in. In yet further embodiments, the conductive wires 308 directly over and coupled to the capacitors 108 may be configured as global reference voltage lines that each connect multiple capacitors 108 in a same column together. In such embodiments, the conductive wires 308 directly over the capacitors 108 are elongated in the direction the gate electrodes 120 are elongated in.

Further, a plurality of capacitors 108 are disposed in the interconnect structure 301 and directly overlie a corresponding one of the write transistors 106. Each capacitor 108 comprises a first electrode 310, a capacitor dielectric layer 312, and a second electrode 314. The capacitor dielectric layer 312 is disposed between the first electrode 310 and the second electrode 314. In some embodiments, the capacitors 108 are each configured as a metal-insulator-metal capacitor, a trench capacitor, or the like. In various embodiments, the first electrode 310 of each capacitor 108 is directly electrically coupled to a corresponding first source/drain region 126a of an underlying write transistor 106. The first and second electrodes 310, 314 may, for example, be or comprise aluminum, titanium, tantalum, tungsten, titanium nitride, tantalum nitride, polysilicon, or the like. The capacitor dielectric layer 312 may, for example, be or comprise silicon dioxide, hafnium oxide, titanium oxide, zirconium oxide, some other dielectric material, or any combination of the foregoing.

By virtue of the gate electrode 120 being disposed laterally between the first and second fin structures 112a, 112b, a length of the channel region 115 is increased. For example, the length of the channel region 115 is greater than the lateral distance 105 between the first and second source/drain regions 126a, 126b. The increased length of the channel region 115 decreases leakage current in the write transistor 106 such that the GCRAM cells 104 have increased data retention time. Accordingly, an overall performance of the integrated chip is increased.

With reference to FIG. 3C, the gate electrodes 120 extend laterally in a first direction (e.g., along the x-axis) and are arranged in parallel with one another. The capacitor 108 (represented as a dashed box) of each GCRAM cell 104 directly overlies the first and second source/drain regions 126a, 126b of the corresponding write transistor 106. In various embodiments, an area of the capacitor 108 is greater than an area of a corresponding write transistor 106. In some embodiments, a length 316 of the first and second fin structures 112a, 112b is greater than the lateral distance 105. In various embodiments, the gate dielectric layer 118 laterally encloses outer perimeters of the first and second fin structures 112a, 112b. In some embodiments, the one or more first conductive wires (308a of FIG. 3B) are elongated in a second direction (e.g., along the y-axis) that is perpendicular to or substantially perpendicular to the first direction.

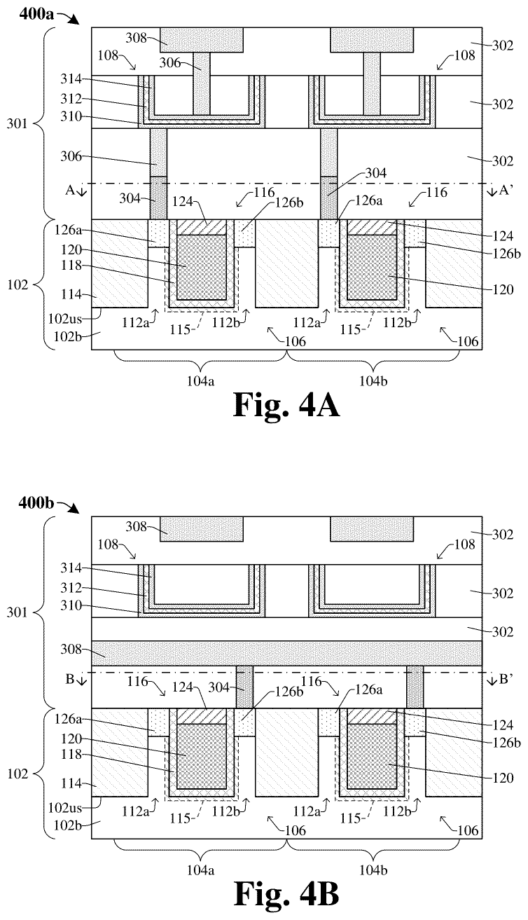

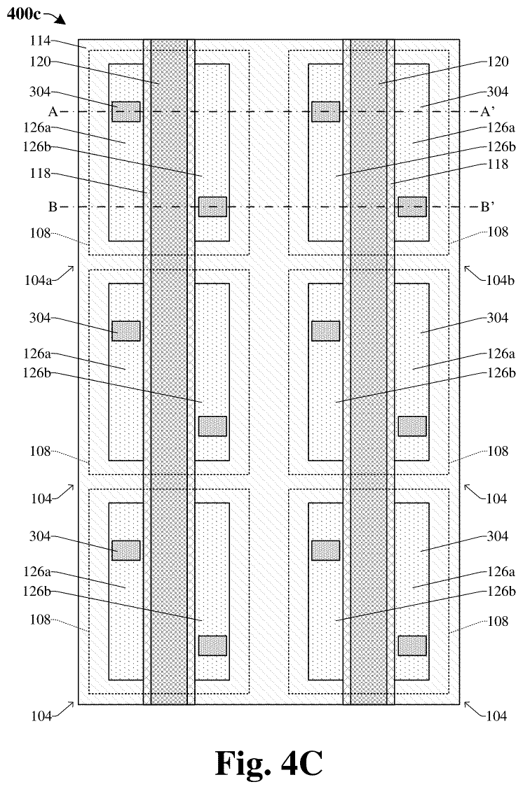

FIGS. 4A-4C illustrate various views of some embodiments of an integrated chip corresponding to some other embodiments of the integrated chip of FIGS. 3A-3C. FIG. 4C illustrates a top view 400c of some embodiments of the integrated chip. FIG. 4A illustrates a cross-sectional view 400a of some embodiments of the integrated chip taken along the line A-A′ of FIG. 4C. FIG. 4B illustrates a cross-sectional view 400b of some embodiments of the integrated chip taken along the line B-B′ of FIG. 4C. It will be appreciated that structures (e.g., the dielectric layer 302 and/or the capping layer 124) from the cross-sectional views 400a and 400b of FIGS. 4A-4B may be omitted from the top view 400c of FIG. 4C for ease of illustration.

As shown in FIGS. 4A-4C, the gate dielectric layer 118 is disposed along opposing sidewalls and a bottom surface of the gate electrode 120. Further, the isolation structure 114 contacts a first sidewall of each of the first and second fin structures 112a, 112b that is opposite a second sidewall of each of the first and second fin structures 112a, 112b, where the second sidewall of each of the first and second fin structures 112a, 112b contacts the gate dielectric layer 118. In various embodiments, a top surface of the gate dielectric layer 118 is coplanar with a top surface of the capping layer 124 and/or a top surface of the isolation structure 114. In addition, as shown in FIG. 4C, the isolation structure 114 contacts at least three sides of the first and second source/drain regions 126a, 126b of each of the GCRAM cells 104. In various embodiments, the isolation structure 114 contacts at least three sidewalls of each of the first and second fin structures 112a, 112b of each of the GCRAM cells 104.

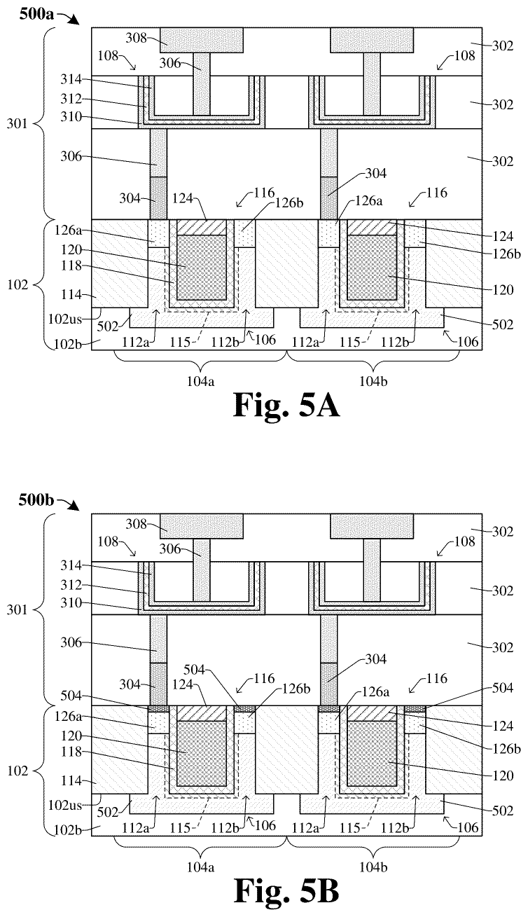

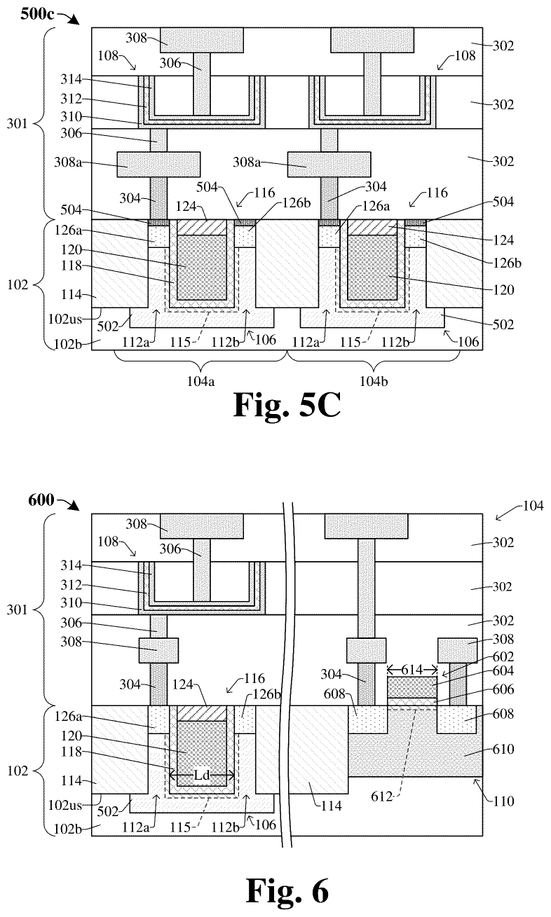

FIG. 5A illustrates a cross-sectional view 500a of some embodiments of an integrated chip that includes a plurality of GCRAM cells that respectively have a transistor with low leakage current. In various embodiments, the integrated chip may correspond to some other embodiments of the integrated chip of FIGS. 3A-3C or 4A-4C, where the integrated chip comprises a plurality of GCRAM cells 104 disposed on the substrate 102.

In various embodiments, the write transistors 106 of each of the GCRAM cells 104 respectively comprise a well region 502 disposed in the substrate 102. In some embodiments, the well region 502 underlies the first and second source/drain regions 126a, 126b and extends along the first and second fin structures 112a, 112b to the base region 102b of the substrate 102. In various embodiments, the first and second source/drain regions 126a, 126b comprise a first doping type and the well region 502 comprises a second doping type opposite the first doping type. In some embodiments, the first doping type is n-type and the second doping type is p-type, or vice versa.

FIG. 5B illustrates a cross-sectional view 500b of some embodiments of an integrated chip corresponding to some other embodiments of the integrated chip of FIG. 5A, where a silicide layer 504 is disposed over each of the source/drain regions 126a, 126b of the write transistors 106. The silicide layer 504 is disposed on a top of the fin structures 112a, 112b. In some embodiments, a top surface of the silicide layer 504 is aligned with the top surface of the isolation structure 114 and/or the top surface of the capping layer 124. The silicide layer 504 may, for example, be or comprise titanium silicide, nickel silicide, cobalt silicide, or the like.

FIG. 5C illustrates a cross-sectional view 500c of some embodiments of an integrated chip corresponding to some other embodiments of the integrated chip of FIG. 5B, where a first conductive wires 308a directly underlie a corresponding capacitor 108 of each of the GCRAM cells 104a, 104b. In some embodiments, the first conductive wires 308a are respectively electrically coupled to a corresponding storage node (SN of FIG. 1) of the GCRAM cells 104a, 104b. For example, each of the conductive wires 308a is electrically coupled to a gate electrode (not shown) of a corresponding read transistor (not shown) of the GCRAM cells 104a, 104b.

FIG. 6 illustrates a cross-sectional 600 of some embodiments of an integrated chip that includes a GCRAM cell having a write transistor and a read transistor disposed on a substrate.

The integrated chip includes a GCRAM cell 104 disposed on a substrate 102. In various embodiments, the GCRAM cell 104 is configured as illustrated and/or described in FIG. 1, 2, 3A-3C, 4A-4C, or 5A-5C. The GCRAM cell 104 comprises the write transistor 106, the capacitor 108, and a read transistor 110. The capacitor 108 directly overlies the write transistor 106 and the read transistor 110 is disposed in a region laterally offset from the write transistor 106.

In some embodiments, the read transistor 110 comprises a read gate structure 602 over the substrate 102 and a pair of source/drain regions 608 disposed in the substrate 102 on opposing sides of the read gate structure 602. The read gate structure 602 comprises a read gate dielectric layer 606 on the substrate 102 and a read gate electrode 604 over the read gate dielectric layer 606. Further, a well region 610 is disposed in the substrate 102 under the read gate structure 602. In various embodiments, a doping type of the well region 610 of the read transistor 110 is opposite the doping type of the well region 502 of the write transistor 106. In various embodiments, tops of the source/drain regions 608 of the read gate structure 602 are coplanar with tops of the source/drain regions 126a, 126b of the write transistor 106. In some embodiments, the top surface of the gate dielectric layer 118 of the write transistor 106 is disposed below a bottom surface of the read gate electrode 604. Further, the read transistor 110 comprises a channel region 612 disposed in the substrate 102 and extending continuously between the pair of source/drain regions 608. In various embodiments, a length of the channel region 612 of the read transistor 110 is equal to or less than a length 614 of the read gate structure 602.

The read transistor 110 may, for example, be configured as a planar MOSFET, a FinFET, a GAAFET, a nanowire FET, a nanosheet FET, or some other type of semiconductor device and/or transistor. In various embodiments, the length of the channel region 612 of the read transistor 110 is less than the length of the channel region 115 of the write transistor 106. In such instances, the read transistor 110 having the shorter channel region 612 facilitates decreasing a lateral footprint of the GCRAM cell 104 and increasing a bit density of the integrated chip. In various embodiments, leakage current from the read transistor 110 during operation of the GCRAM cell 104 is relatively small. Therefore, the length of the channel region 612 of the read transistor 110 being less than that of the channel region 115 of the write transistor 106 facilitates the GCRAM cell 104 having the increased data retention time while decreasing fabrication complexity and/or decreasing a lateral footprint of the GCRAM cell 104. In further embodiments, the read transistor 110 being configured as a planar MOSET facilitates the read transistor 110 being formed with logic transistors (not shown) formed on the substrate 102, thereby decreasing a fabrication complexity or cost of the integrated chip.

FIG. 7 illustrates a circuit diagram 700 of some embodiments of an integrated chip having a GCRAM cell comprising a write transistor, a first read transistor, and a second read transistor.

The integrated chip comprises a GCRAM cell 104. In some embodiments, the GCRAM cell 104 comprises a write transistor 106, a capacitor 108, a first read transistor 110, and a second read transistor 702. In various embodiments, the write transistor 106 is configured as illustrated and/or described in FIGS. 1, 2, 3A-3C, 4A-4C, 5A-5C, or 6 and has a relatively long channel region. The GCRAM cell 104 may be referred to as or configured as a three-transistor one-capacitor (3T1C) memory cell. Source/drain regions of the write transistor 106 are coupled between the write bit line WBL and the storage node SN. A gate electrode of the write transistor 106 is coupled to the write word line WWL. The capacitor 108 is coupled between the storage node SN and a reference voltage (e.g., ground). A gate electrode of the first read transistor 110 is coupled to the storage node SN. A first source/drain region of the first read transistor 110 is coupled to a voltage source 704. A second source/drain region of the first read transistor 110 is coupled to a first source/drain region of the second read transistor 702. A second source/drain region of the second read transistor 702 is coupled to the read bit line RBL. Further, a gate of the second read transistor 702 is coupled to the read write line RWL. In some embodiments, the write transistor 106 is configured as a p-type transistor and the first and second read transistors 110, 702 are each configured as an n-type transistor, or vice versa. In further embodiments, the write transistor 106 and the first and second read transistors 110, 702 may each be configured as a p-type transistor or and n-type transistor.

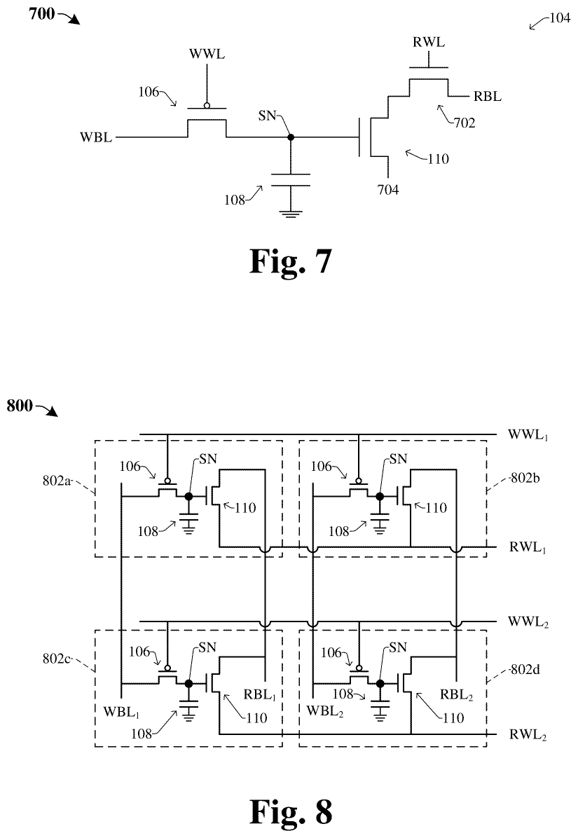

FIG. 8 illustrates a circuit diagram 800 of some embodiments of an integrated chip comprising a plurality of GCRAM cells 802a-d disposed in a memory array. In some embodiments, each of the GCRAM cells 802a-d are configured as illustrated and/or described in FIGS. 1, 2, 3A-3C, 4A-4C, 5A-5C, or 6. It will be appreciated that while the circuit diagram 800 illustrates each of the GCRAM cells 802a-d having a 2T1C configuration, the GCRAM cells 802a-d may each have a 3T1C configuration as illustrated and/or described in FIG. 7. Each of the GCRAM cells 802a-d comprise the write transistor 106, the capacitor 108, and the read transistor 110. The plurality of GCRAM cells 802a-d includes a first GCRAM cell 802a, a second GCRAM cell 802b, a third GCRAM cell 802c, and a fourth GCRAM cell 802d.

The integrated chip comprises a plurality of write word lines WWL₁, WWL₂, a plurality of write bit lines WBL₁, WBL₂, a plurality of read word lines RWL₁, RWL₂, and a plurality of read bit lines RBL₁, RBL₂. The memory array is coupled to support circuitry (not shown) that is configured to perform read operations, write operations, and/or refresh operations on the plurality of GCRAM cells 802a-d. During operation of the integrated chip, suitable bias conditions are applied to the write word lines WWL₁, WWL₂, the write bit lines WBL₁, WBL₂, the read word lines RWL₁, RWL₂, and the read bit lines RBL₁, RBL₂ to perform a read operation and/or a write operation on at least one of the GCRAM cells. In various embodiments, while a read and/or write operation is performed on the at least one of the GCRAM cells, one or more other GCRAM cells in the memory array may be held in a standby mode. As discussed in further detail below, the write transistor 106 of each GCRAM cell 802a-d having the relatively long channel region (e.g., as illustrated and/or described in FIG. 1) increases a duration in which the at least one GCRAM cell held in the standby mode retains its data state. As a result, a frequency of refresh operations performed on the memory array is decreased, thereby decreasing a power consumption of the integrated chip.

In various embodiments, in a first operation the first GCRAM cell 802a is storing a first data state (e.g., a logical “0”) at the storage node SN of the first GCRAM cell 802a and is held in a standby mode while performing a first write operation on the third GCRAM cell 802c. During the first write operation on the third GCRAM cell 802c, a first write word line WWL₁, a first read write line RWL₁, and a first write bit line WBL₁ are biased with a supply voltage Vdd. In various embodiments, the supply voltage Vdd may, for example, be within a range of about 1 to 5 volts or some other suitable value. Further, during the first write operation a second write word line WWL₂ is biased with a reference voltage (e.g., 0 volts). Under such biasing conditions, a data state at a storage node SN of the third GCRAM cell 802c is set to a logical “1” and the write transistor 106 of the first GCRAM cell 802a is in an off state. However, leakage from the write transistor 106 of the first GCRAM cell 802a may cause charge to build up at the storage node SN of the first GCRAM cell 802a, thereby potentially changing the first data state at the storage node SN to a second data state (e.g., a logical “1”) while the first GCRAM cell 802a is held in the standby mode. By virtue of the write transistor 106 of the first GCRAM cell 802a having a relatively long channel region (e.g., as illustrated and/or described in FIG. 1), leakage current from the write transistor 106 of the first GCRAM cell 802a while performing the first write operation on the third GCRAM cell 802c is reduced. As a result, charge build up at the storage node SN of the first GCRAM cell 802a while performing the first write operation on the third GCRAM cell 802c is reduced, thereby increasing a time in which the first GCRAM cell 802a holds the first data state (e.g., a logical “0”) while held in the standby mode. Accordingly, data retention of the GCRAM cells 802a-d is increased and a frequency of refresh operations performed on the plurality of GCRAM cells 802a-d is decreased, thereby decreasing a power consumption of the integrated chip.

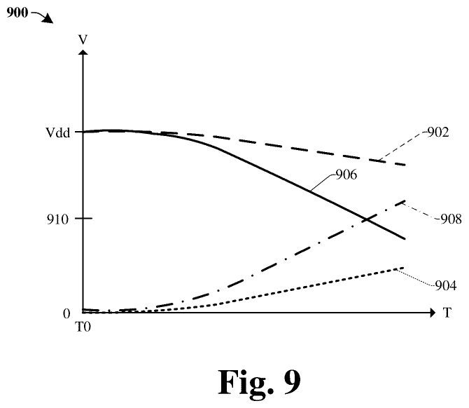

FIG. 9 illustrates a graph 900 comprising a series of voltage curves of some embodiments of GCRAM cells during different operation conditions. These voltage curves reflect a change of voltage at a storage node of a corresponding GCRAM cell while held in a standby mode. In various embodiments, the voltage curves 902, 904 correspond to voltage values at the storage node of a GCRAM cell as previously illustrated and/or described in FIG. 1. Other voltage curves 906, 908 represent voltage values at a storage node of a second GCRAM cell that comprises a write transistor with a channel region having a relatively short length.

More particularly in FIG. 9, the voltage curves 902, 904 relate to some embodiments in accordance with the present disclosure, in which the GCRAM cell includes a write transistor having a relatively long channel region. The voltage curves 902, 904 depict a voltage at a storage node of the GCRAM cell when held in the standby mode. For example, a first voltage curve 902 depicts the voltage at the storage node when the GCRAM cell is storing a first data state (e.g., a logical “1”) at an initial time TO and is subsequently placed in the standby mode. In addition, a second voltage curve 904 depicts the voltage at the storage node when the GCRAM cell is storing a second data state (e.g., a logical “0”) at the initial time TO and is subsequently placed in the standby mode.

In various embodiments, the other voltage curves 906, 908 depict a voltage at a storage node of the second GCRAM cell when held in the standby mode. For example, a third voltage curve 906 depicts a voltage at the storage node of the second GCRAM cell when initially storing the first data state (e.g., a logical “1”) and a fourth voltage curve 908 depicts a voltage at the storage node of the second GCRAM cell when initially storing the second data state (e.g., a logical “0”). As can be seen by a comparison of the first and second curves 902, 904 and the third and fourth voltage curves 906, 908, the second GCRAM cell that comprises the write transistor with the relatively short channel region suffers from a short data retention time. For example, the third and fourth voltage curves 906, 908 decrease to or increase to a voltage 910 more quickly than the first and second voltage curves 906, 908. In various embodiments, the voltage 910 is about half of a supply voltage Vdd. As a result, refresh operations are performed more often on the second GCRAM cell than on the GCRAM cell comprising the write transistor with the relatively long channel region. Therefore, the write transistor having the relatively long channel region increases a duration in which the GCRAM cell accurately retains its data state and decreases a frequency of refresh operations performed on the GCRAM cell.

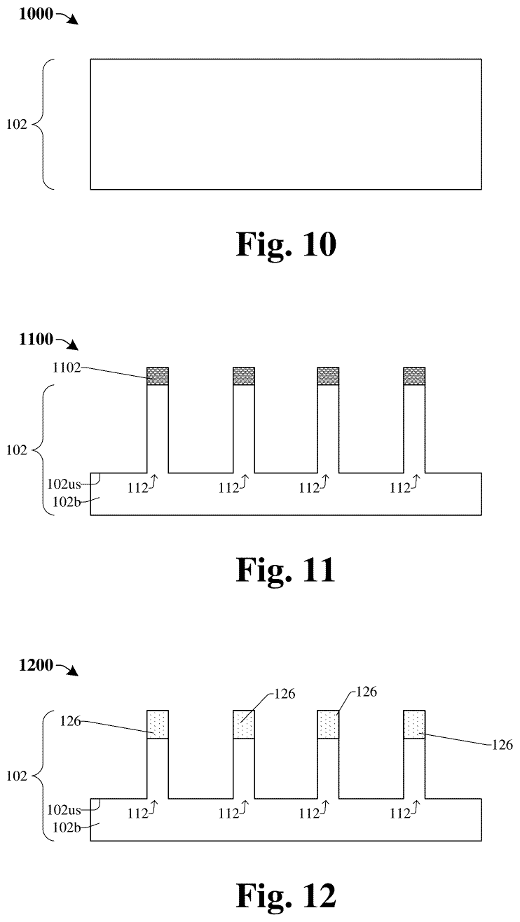

FIGS. 10-21 illustrate cross-sectional views 1000-2100 of some embodiments of a method of forming an integrated chip that includes a GCRAM cell having a transistor with low leakage current. Although the cross-sectional views 1000-2100 shown in FIGS. 10-21 are described with reference to a method, it will be appreciated that the structures shown in FIGS. 10-21 are not limited to the method but rather may stand along separate of the method. Although FIGS. 10-21 are described as a series of acts, it will be appreciated that these acts are not limiting in that the order of the acts can be altered in other embodiments, and the methods disclose are also applicable to other structures. In other embodiments, some acts that are illustrated and/or described may be omitted in whole or in part.

As shown in cross-sectional view 1000 of FIG. 10, a substrate 102 is provided. The substrate 102 may, for example, be or comprise a bulk substrate (e.g., bulk silicon), a silicon-on-insulator (SOI) substrate, germanium, gallium, one or more epitaxial layers (e.g., epitaxial silicon), some other suitable substrate material, or the like.

A shown in cross-sectional view 1100 of FIG. 11, a patterning process is performed on the substrate 102 to form a plurality of fin structures 112 vertically extending from an upper surface 102us of a base region 102b of the substrate 102. In some embodiments, the patterning process includes forming a masking layer 1102 over the substrate 102 and performing an etching process (e.g., a dry etch and/or a wet etch) on the substrate 102 according to the masking layer 1102. The etching process may, for example, include a dry etch process such as a reactive-ion etch process, a plasma etch process, or the like. The masking layer 1102 may, for example, be or comprise a photoresist (e.g., positive/negative photoresist), a hardmask (e.g., comprising silicon nitride, silicon dioxide, some other suitable material, or any combination of the foregoing), etc. Further, after the patterning process a stripping process is performed (e.g., an ashing process, a wet etch process, etc.) to remove the masking layer 1102 (not shown).

As shown in cross-sectional view 1200 of FIG. 12, a plurality of source/drain regions 126 are formed on top regions of the plurality of fin structures 112. The source/drain regions 126 may, for example, be or comprise a doped region of the fin structures 112, doped epitaxial silicon, or the like. In various embodiments, the plurality of source/drain regions 126 may have a first doping type (e.g., p-type) or a second doping type (e.g., n-type). In various embodiments, the source/drain regions 126 may be formed by a selective doping process, an epitaxial process, or some other suitable fabrication process. In some embodiments, the selective doping process includes forming a masking layer (not shown) over the substrate 102 and implanting one or more dopants into the fin structures 112 according to the masking layer. In yet further embodiments, after the selective doping process, a silicide layer is formed over the plurality of source/drain regions 126. The silicide layer may, for example, be formed by depositing a conductive layer on the source/drain regions 126 and performing a thermal annealing process to convert top regions of the fin structures 112 into a silicide.

In yet further embodiments, a selective doping process is performed on the substrate 102 to form a well region (not shown) within the fin structures 112 and along the upper surface 102us of the base region 102b. In such embodiments, the well region may be configured as the well region (502 of FIG. 5) as illustrated and/or described in FIG. 5. In various embodiments, the well region is formed before the source/drain regions 126.

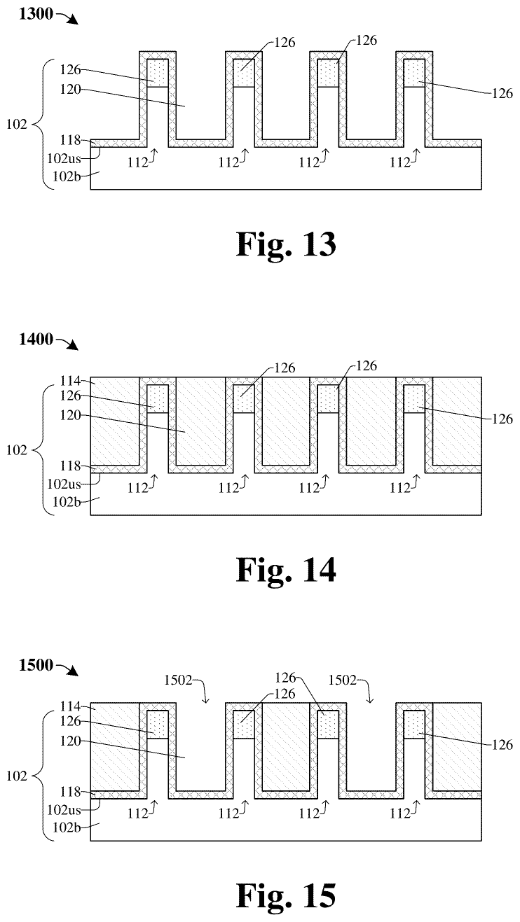

As shown in cross-sectional view 1300 of FIG. 13, a gate dielectric layer 118 is formed over the substrate 102. In some embodiments, the gate dielectric layer 118 is conformally formed along opposing sidewalls of each fin structure 112, sides and a top of each source/drain region 126, and the upper surface 102us. In various embodiments, the gate dielectric layer 118 is formed over the substrate 102 by, for example, a chemical vapor deposition (CVD) process, an atomic layer deposition (ALD) process, a physical vapor deposition (PVD) process, or some other suitable growth or deposition process. The gate dielectric layer 118 may, for example, be or comprise silicon dioxide, hafnium oxide, aluminum oxide, some other dielectric material, or any combination of the foregoing.

As shown in cross-sectional view 1400 of FIG. 14, an isolation structure 114 is formed over the base region 102b of the substrate 102 and between adjacent fin structures 112. In some embodiments, forming the isolation structure 114 includes depositing (e.g., by CVD, PVD, ALD, etc.) a dielectric material (e.g., silicon oxide, silicon nitride, silicon carbide, etc.) over the base region 102b and performing a planarization process (e.g., a chemical mechanical planarization (CMP) process) into the dielectric material. In various embodiments, a top surface of the gate dielectric layer 118 is coplanar with a top surface of the isolation structure 114.

As shown in cross-sectional view 1500 of FIG. 15, a patterning process is performed on the isolation structure 114 to form a plurality of gate electrode openings 1502 between corresponding pairs of the fin structures 112. In some embodiments, the patterning process includes: forming a masking layer (not shown) over the substrate 102; performing an etching process (e.g., a dry etch and/or a wet etch) on the isolation structure 114 according to the masking layer to form the gate electrode openings 1502; and performing a stripping process (e.g., an ashing process, a wet etch process, etc.) to remove the masking layer.

As shown in cross-sectional view 1600, gate electrodes 120 and capping layers 124 are formed in the plurality of gate electrode openings (1502 of FIG. 15), thereby defining gate structures 116 for corresponding write transistors 106 of first and second GCRAM cells 104a, 104b. In various embodiments, a process for forming the write transistors 106 includes the processing steps illustrated and/or described in FIGS. 11-16. The gate electrodes 120 are disposed between corresponding fin structures 112 and extend continuously in a first lateral direction (e.g., into the page) that is parallel to elongated sidewalls of the fin structures 112 (e.g., as illustrated and/or described in the top view 300c of FIG. 3C). In various embodiments, forming the gate structures 116 between corresponding fin structures 112 increases a length of a channel region (e.g., 115 of FIG. 1) of each write transistor 106 as illustrated and/or described in FIG. 1. As a result, leakage current of the write transistors 106 is decreased, thereby increasing an overall performance of the GCRAM cells 104a, 104b and increasing a bit density over the substrate 102.

In some embodiments, a process for forming the gate electrodes 120 includes depositing (e.g., by CVD, PVD, sputtering, electroless plating, electroplating, etc.) a conductive material (e.g., doped polysilicon such as n-doped polysilicon or p-typed polysilicon, one or more metals such as titanium, aluminum, titanium nitride, tantalum nitride, etc.) in the gate electrode openings (1502 of FIG. 15) and performing an etch back process (e.g., a dry etch) into the conductive material to recess the gate electrodes 120 below the top surface of the isolation structure 114. In various embodiments, a process for forming the capping layers 124 includes depositing (e.g., by CVD, PVD, ALD, etc.) a dielectric material (e.g., silicon nitride, silicon dioxide, aluminum oxide, etc.) over the gate electrodes 120 and filling a remaining portion of the gate electrode openings (1502 of FIG. 15) and performing a planarization process (e.g., a CMP process) into the dielectric material.

In various embodiments, a read transistor (e.g., 110 of FIG. 6) of each of the GCRAM cells 104a, 104b may be formed after forming the write transistors 106 and before subsequent processing steps (e.g., before the processing steps of FIG. 17). The read transistor (e.g., 110 of FIG. 6) may be configured as a planar MOSFET, a FinFET, a GAAFET, or some other suitable transistor device. In embodiments in which the read transistor (e.g., 110 of FIG. 6) is configured as a FinFET, a corresponding fin structure of the read transistor (e.g., 110 of FIG. 6) may be formed concurrently with the plurality of fin structures 112 of the write transistors 106. In such embodiments, other structures of the read transistor (e.g., 110 of FIG. 6) such as a gate electrode and/or source/drain regions of the read transistor (e.g., 110 of FIG. 6) may be formed concurrently with corresponding structures/features of the write transistors 106. Thus, formation of the write transistors 106 is compatible with current CMOS fabrication processes and forming features of the read transistor (e.g., 110 of FIG. 6) concurrently with the corresponding structures/features of the write transistors 106 reduces manufacturing costs and time.

As shown in cross-sectional view 1700 of FIG. 17, a plurality of conductive contacts 304 and a plurality of conductive vias 306 are formed in a dielectric layer 302 over corresponding source/drain regions 126 of the write transistors 106. In various embodiments, the conductive contacts 304 and the conductive vias 306 are part of a lower portion of an interconnect structure (e.g., 302 of FIG. 21). The conductive vias 306 overlie the conductive contacts 304. In some embodiments, forming the conductive contacts 304 includes: depositing (e.g., by CVD, PVD, ALD, etc.) a first dielectric material (e.g., an oxide such as silicon dioxide, a low-k dielectric material, etc.) over the substrate 102; patterning the first dielectric material to form a plurality of contact openings over the write transistors 106; depositing a conductive material (e.g., copper, tungsten, cobalt, tantalum, etc.) in the plurality of contact openings; and performing a planarization process (e.g., a CMP process) into the conductive material. In various embodiments, the plurality of conductive vias 306 may, for example, be formed by a single damascene process, a dual damascene process, or some other suitable fabrication process. The conductive vias 306 may, for example, be formed in a second dielectric material (e.g., an oxide such as silicon dioxide, a low-k dielectric material, etc.) over the conductive contacts 304, where the first and second dielectric materials are part of the dielectric layer 302.

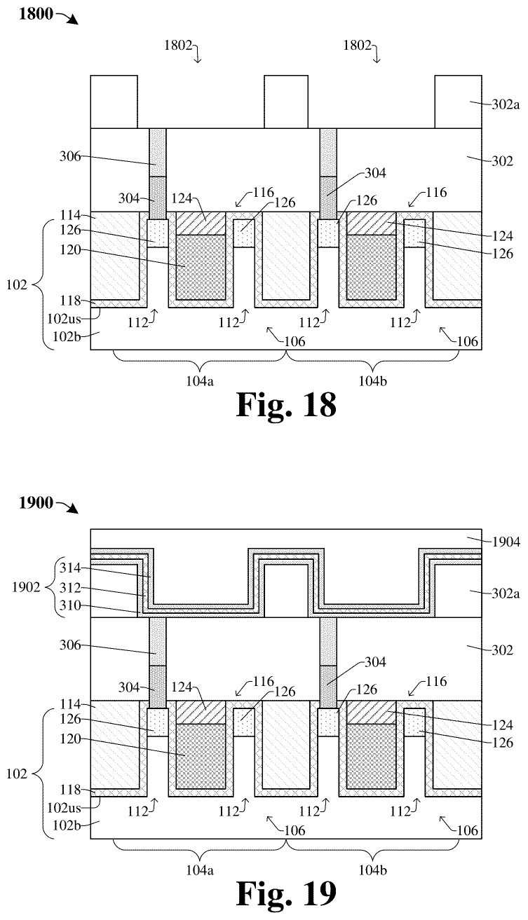

As shown in cross-sectional view 1800 of FIG. 18, an upper dielectric layer 302a is formed over the substrate 102 and is subsequently patterning to form a plurality of capacitor openings 1802 in the upper dielectric layer 302a. The upper dielectric layer 302a may, for example, be or comprise silicon dioxide, a low-k dielectric material, silicon nitride, silicon carbide, some other dielectric material, or any combination of the foregoing. In some embodiments, patterning the upper dielectric layer 302a includes: forming a masking layer (not shown) over the upper dielectric layer 302a; performing an etching process (e.g., a dry etch and/or a wet etch) on the upper dielectric layer 302a according to the masking layer to form the capacitor openings 1802; and performing a stripping process (e.g., an ashing process, a wet etch process, etc.) to remove the masking layer.

As shown in cross-sectional view 1900 of FIG. 19, a plurality of capacitor layers 1902 and a dielectric layer 1904 are formed in the plurality of capacitor openings (1802 of FIG. 18). The plurality of capacitor layers 1902 comprise a first electrode 310 over the dielectric layer 302, a capacitor dielectric layer 312 over the first electrode 310, and a second electrode 314 over the capacitor dielectric layer 312. The dielectric layer 1904 overlies the second electrode 314. The plurality of capacitor layers 1902 and the dielectric layer 1904 are each formed by corresponding individual deposition process. In some embodiments, the individual deposition process may, for example, be or comprise CVD, PVD, ALD, sputtering, electro plating, electroless plating, or some other suitable growth or deposition process.

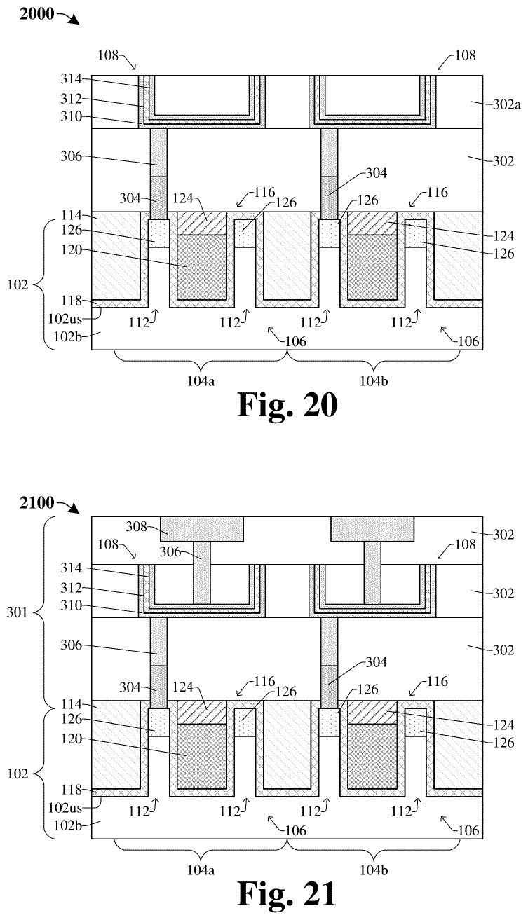

As shown in cross-sectional 2000 of FIG. 20, a planarization process (e.g., a CMP process) is performed into the plurality of capacitor layers (1902 of FIG. 19) and the dielectric layer (1904 of FIG. 19), thereby forming capacitors 108. Each of the first and second GCRAM cells 104a, 104b comprise a corresponding one of the capacitors 108. In various embodiments, a process for forming the capacitors 108 includes the processing steps illustrated and/or described in FIGS. 18-20. In some embodiments, a process for forming the GCRAM cells 104a, 104b includes the processing steps illustrated and/or described in FIGS. 11-20. Each capacitor 108 comprises the first electrode 310, the capacitor dielectric layer 312, and the second electrode 314.

As shown in cross-sectional view 2100 of FIG. 2100, a dielectric layer 302, a plurality of conductive wires 308, and another level of the conductive vias 306 are formed over the capacitors 108, thereby defining an interconnect structure 301. In some embodiments, the plurality of conductive wires 308 and the another level of the conductive vias 306 are part of an upper portion of the interconnect structure 301. In various embodiments, the conductive wires 308 and the another level of conductive vias 306 may, for example, be formed by a single damascene process, a dual damascene process, or some other suitable fabrication process. Further, the dielectric layer 302 may, for example, be formed by a CVD process, a PVD process, an ALD process, or some other suitable deposition or growth process.

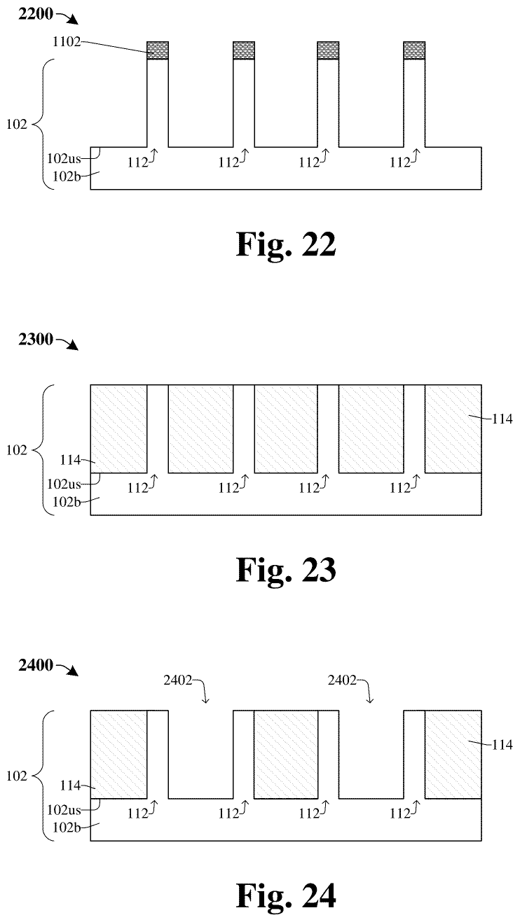

FIGS. 22-26 illustrate various cross-sectional views 22-26 of some embodiments of acts that may be performed in place of the acts at FIGS. 11-16, such that the method of FIGS. 10-21 may alternatively proceed from FIG. 10 to FIGS. 22-26, and then from FIG. 26 to FIGS. 17-21 (i.e., skipping FIGS. 11-16). In various embodiments, FIGS. 22-26 illustrate other embodiments of forming the write transistor (106 of FIG. 26) of the GCRAM cells (104a, 104b of FIG. 26).

As shown in cross-sectional view 2200 of FIG. 22, a patterning process is performed on a substrate 102 to form a plurality of fin structures 112 vertically extending from an upper surface 102us of a base region 102b of the substrate 102. In some embodiments, the patterning process is performed as illustrated and/or described in FIG. 11. In various embodiments, a selective doping process is performed on the substrate 102 to form well regions (not shown) within the fin structures 112 and along the upper surface 102us of the base region 102b. In such embodiments, the well region may be configured as the well region (502 of FIG. 5) as illustrated and/or described in FIG. 5.

As shown in cross-sectional view 2300 of FIG. 23, an isolation structure 114 is formed over the base region 102b of the substrate and between adjacent fin structures 112. In some embodiments, forming the isolation structure 114 includes depositing (e.g., by CVD, PVD, ALD, etc.) a dielectric material (e.g., silicon oxide, silicon nitride, silicon carbide, etc.) over the base region 102b and performing a planarization process (e.g., a chemical mechanical planarization (CMP) process) into the dielectric material. In various embodiments, a top surface of the isolation structure 114 is coplanar with a top surface of the plurality of fin structures 112.

As shown in cross-sectional view 2400 of FIG. 24, a patterning process is performed on the isolation structure 114 to form a plurality of gate structure openings 2402 between corresponding pairs of the fin structures 112. In some embodiments, the patterning process includes: forming a masking layer (not shown) over the substrate 102; performing an etching process (e.g., a dry etch and/or a wet etch) on the isolation structure 114 according to the masking layer to form the gate structure openings 2402; and performing a stripping process (e.g., an ashing process, a wet etch process, etc.) to remove the masking layer.

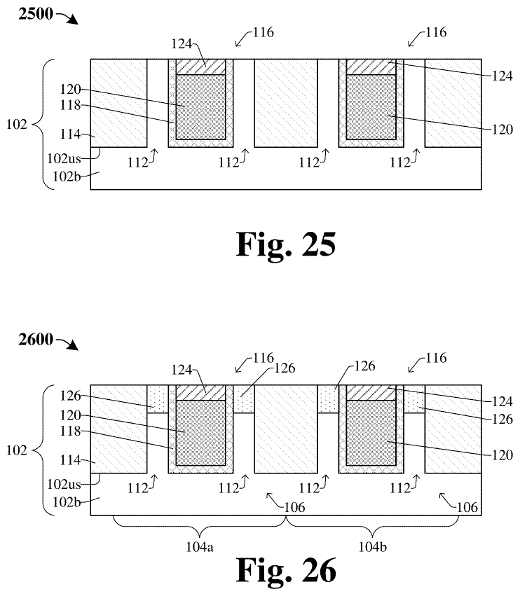

As shown in cross-sectional view 2500 of FIG. 25, gate structures 116 are formed within the plurality of gate structure openings (2402 of FIG. 24). The gate structures 116 respectively comprise a gate dielectric layer 118 lining a corresponding gate structure opening (2402 of FIG. 25), a gate electrode 120 spaced between sidewalls of the gate dielectric layer 118, and a capping layer 124 over the gate electrode 120. In some embodiments, forming the gate structures 116 includes: depositing (e.g., by CVD, PVD, ALD, etc.) the gate dielectric layer 118 over the substrate 102 and lining the gate structure openings (2402 of FIG. 24); depositing (e.g., by CVD, PVD, electroplating, electroless plating, sputtering, etc.) the gate electrode 120 over the gate dielectric layer 118 and partially filling the gate structure openings (2402 of FIG. 24); and depositing the capping layer 124 over the gate electrode 120 and filling a remaining portion of the gate structure openings (2402 of FIG. 24). In various embodiments, after depositing layers of the gate structures 116 over the substrate 102 and within the gate structure openings (2402 of FIG. 24), a planarization process is performed into the layers of the gate structures 116. In further embodiments, top surfaces of the gate dielectric layer 118 and the capping layer 124 are coplanar with top surfaces of the fin structures 112 and/or the top surface of the isolation structure 114.

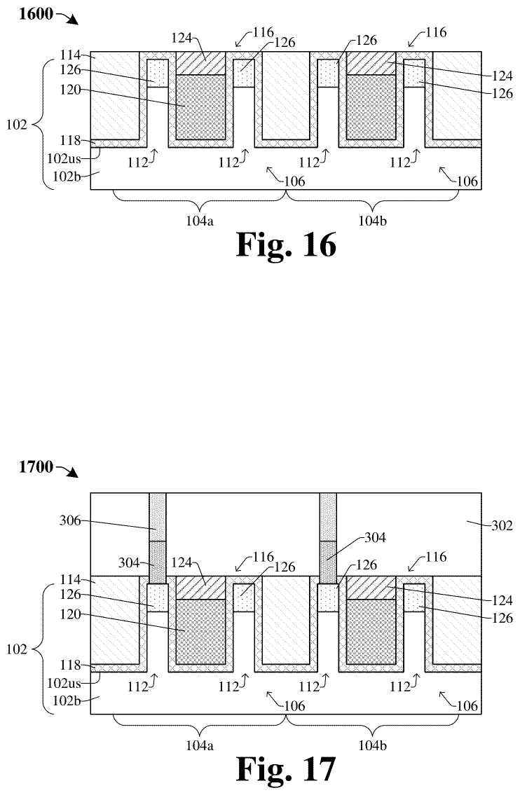

As shown in cross-sectional view 2600 of FIG. 26, a plurality of source/drain regions 126 are formed on top regions of the plurality of fin structures 112, thereby defining write transistors 106 of first and second GCRAM cells 104a, 104b. In some embodiments, a process for forming the write transistors 106 includes the processing steps illustrated and/or described in FIGS. 22-26. The source/drain regions 126 may, for example, be or comprise a doped region of the fin structures 112, doped epitaxial silicon, or the like. In various embodiments, the plurality of source/drain regions 126 may have a first doping type (e.g., p-type) or a second doping type (e.g., n-type). In various embodiments, the source/drain regions 126 may be formed by a doping process, an epitaxial process, or some other suitable fabrication process. In some embodiments, the doping process includes implanting one or more dopants into the fin structures 112. In yet further embodiments, after the doping process, a silicide layer is formed over the plurality of source/drain regions 126. The silicide layer may, for example, be formed by depositing a conductive layer on the source/drain regions 126 and performing a thermal annealing process to convert top regions of the fin structures 112 into a silicide. In further embodiments, a read transistor (e.g., 110 of FIG. 6) of each of the GCRAM cells 104a, 104b may be formed as described in FIG. 16 above.

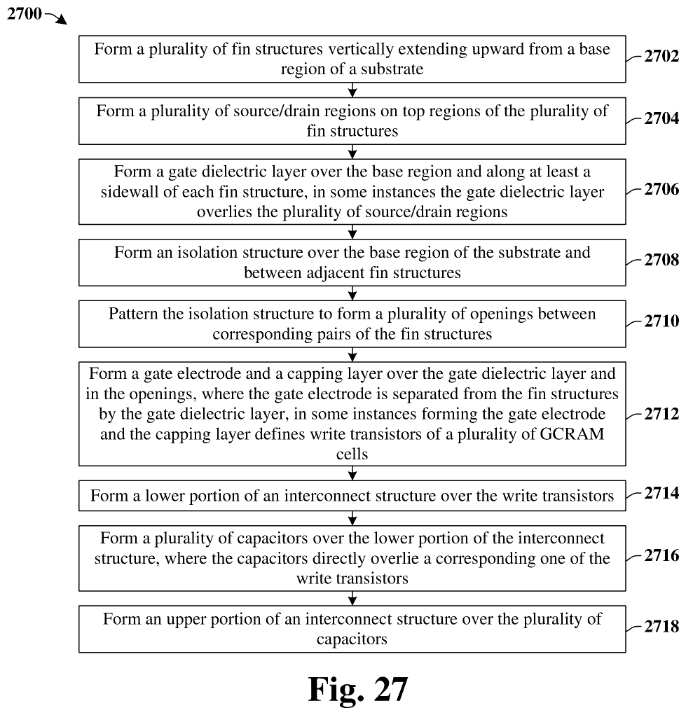

FIG. 27 illustrates a flow diagram of some embodiments of a method 2700 of forming an integrated chip that includes a GCRAM cell having a transistor with low leakage current. While the method 2700 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 2702, a plurality of fin structures are formed extending upward from a base region of a substrate. FIG. 11 illustrates a cross-sectional view 1100 of some embodiments corresponding to act 2702. FIG. 22 illustrates a cross-sectional view 2200 of some other embodiments corresponding to act 2702.

At act 2704, a plurality of source/drain regions are formed on top regions of the plurality of fin structures. FIG. 12 illustrates a cross-sectional view 1200 of some embodiments corresponding to act 2704. FIG. 26 illustrates a cross-sectional view 2600 of some other embodiments corresponding to act 2704.

At act 2706, a gate dielectric layer is formed over the base region and along at least a sidewall of each fin structure. In some instances, the gate dielectric layer overlies the plurality of source/drain regions. FIG. 13 illustrates a cross-sectional view 1300 of some embodiments corresponding to act 2706. FIG. 25 illustrates a cross-sectional view 2500 of some other embodiments corresponding to act 2706.

At act 2708, an isolation structure is formed over the base region of the substrate and between adjacent fin structures. FIG. 14 illustrates a cross-sectional view 1400 of some embodiments corresponding to act 2708. FIG. 23 illustrates a cross-sectional view 2300 of some other embodiments corresponding to act 2708.

At act 2710, the isolation structure is patterned to form a plurality of openings between corresponding pairs of the fin structures. FIG. 15 illustrates a cross-sectional view 1500 of some embodiments corresponding to act 2710. FIG. 24 illustrates a cross-sectional view 2500 of some other embodiments corresponding to act 2710.

At act 2712, a gate electrode and a capping layer are formed over the gate dielectric layer and in the openings, where the gate electrode is separated from the fin structures by the gate dielectric layer. In some instances, forming the gate electrode and the capping layer defines write transistors of a plurality of GCRAM cells. FIG. 16 illustrates a cross-sectional view 1600 of some embodiments corresponding to act 2712. FIG. 25 illustrates a cross-sectional view of some other embodiments corresponding to act 2712.

At act 2714, a lower portion of an interconnect structure is formed over the write transistors. FIG. 17 illustrates a cross-sectional view 1700 of some embodiments corresponding to act 2714.

At act 2716, a plurality of capacitors are formed over the lower portion of the interconnect structure, where the capacitors directly overlie a corresponding one of the write transistors. FIGS. 18-20 illustrate cross-sectional views 1800-2000 of some embodiments corresponding to act 2716.

At act 2718, an upper portion of an interconnect structure is formed over the plurality of capacitors. FIG. 21 illustrates a cross-sectional view 2100 of some embodiments corresponding to act 2718.

Accordingly, in some embodiments, the present application relates to a GCRAM cell comprising a transistor having a gate electrode disposed between a first fin structure and a second fin structure.

In some embodiments, the present application relates to an integrated chip. The integrated chip includes a first fin structure disposed on a base region of a substrate; a second fin structure disposed on the base region of the substrate; a first source/drain region disposed on the first fin structure; a second source/drain region disposed on the second fin structure; and a gate structure over the base region of the substrate and spaced laterally between the first and second fin structures, wherein a bottom surface of the gate structure is disposed below bottoms of the first and second source/drain regions. In some embodiments, a channel region is disposed in the substrate and extends along opposing sidewalls and the bottom surface of the gate structure. In some embodiment, a length of the channel region is greater than a distance between the first source/drain region and the second source/drain region. In some embodiments, the gate structure comprises a gate electrode overlying a gate dielectric layer, wherein the gate electrode, the first fin structure, and the second fin structure extend along a first direction and are substantially parallel to one another. In some embodiments, the integrated chip further includes an isolation structure overlying the base region of the substrate and abutting the first and second fin structures on opposite sides of the gate structure, wherein a top surface of the gate electrode is disposed below a top surface of the isolation structure. In some embodiments, lengths of the first and second fin structures are less than a length of the gate electrode. In some embodiments, the integrated chip further includes a capacitor overlying the first fin structure, wherein a first electrode of the capacitor is electrically coupled to the first source/drain region and a second electrode of the capacitor is electrically coupled to a reference voltage node; and a read transistor comprising a gate electrode electrically coupled to the first source/drain region and the first electrode of the capacitor, wherein source/drain regions of the read transistor are coupled between a read bit line and a read write line. In some embodiments, the second source/drain region is electrically coupled to a write bit line and the gate structure is coupled to a write word line.

In some embodiments, the present disclosure relates to an integrated chip. The integrated chip includes a capacitor overlying a substrate and comprising a first electrode electrically coupled to a storage node; and a first transistor disposed on the substrate, wherein the first transistor comprises a first fin structure, a second fin structure, a first source/drain region, a second source/drain region, and a gate structure, wherein the first and second fin structures extend upward from a base region of the substrate and are laterally offset from one another, wherein the gate structure is disposed between the first and second fin structures, wherein the first and second source/drain regions overlie a corresponding one of the first and second fin structures, wherein the first source/drain region is electrically coupled to the storage node. In some embodiments, the integrated chip further includes a second transistor disposed on the substrate, wherein the second transistor comprises a gate electrode coupled to the storage node. In some embodiments, a first length of a first channel region of the first transistor is greater than a second length of a second channel region of the second transistor. In some embodiments, the second channel region of the second transistor extends continuously along a top surface of the substrate directly between a pair of source/drain regions of the second transistor, wherein the first channel region of the first transistor extends in vertical directions along sidewalls of the gate structure and in a horizontal direction along a bottom surface of the gate structure. In some embodiments, the gate structure comprises a gate dielectric layer and a gate electrode, wherein the gate dielectric layer is spaced between the gate electrode and the first and second fin structures, wherein a top surface of the gate dielectric layer is vertically above a top surface of the gate electrode. In some embodiments, tops of the first and second source/drain regions are aligned with the top surface of the gate dielectric layer. In some embodiments, the integrated chip further includes an isolation structure over the base region of the substrate and on opposing sides of the first and second fin structures, wherein the isolation structure contacts a first sidewall of the first fin structure opposite a second sidewall of the first fin structure, wherein the second sidewall contacts the gate dielectric layer. In some embodiments, a height of the isolation structure is greater than a height of the gate electrode.

In yet other embodiments, the present disclosure relates to a method of forming an integrated chip. The method includes patterning a substrate to form a first fin structure and a second fin structure over a base region of the substrate; forming a first source/drain region on the first fin structure and a second source/drain region on the second fin structure; depositing a gate dielectric layer over the substrate and along sidewalls of the first and second fin structures; and forming a gate electrode over the gate dielectric layer and laterally between the first and second fin structures. In some embodiments, the first and second source/drain regions are formed before depositing the gate dielectric layer, wherein the gate dielectric layer extends along tops of the first and second source/drain regions. In some embodiments, the method further includes forming an isolation structure over the base region of the substrate and on opposing sides of the first and second fin structures, wherein a top surface of the gate electrode is recessed below a top surface of the isolation structure. In some embodiments, the first fin structure has a first sidewall opposite a second sidewall, wherein the gate dielectric layer directly contacts the first sidewall and wherein the isolation structure directly contacts the second sidewall.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
a first fin structure disposed on a base region of a substrate;
a second fin structure disposed on the base region of the substrate;
a first source/drain region disposed on the first fin structure;
a second source/drain region disposed on the second fin structure; and
a gate structure over the base region of the substrate and spaced laterally between the first and second fin structures, wherein a bottom surface of the gate structure is disposed below bottoms of the first and second source/drain regions.

2. The integrated chip of claim 1, wherein a channel region is disposed in the substrate and extends along opposing sidewalls and the bottom surface of the gate structure.

3. The integrated chip of claim 2, wherein a length of the channel region is greater than a distance between the first source/drain region and the second source/drain region.

4. The integrated chip of claim 1, wherein the gate structure comprises a gate electrode overlying a gate dielectric layer, wherein the gate electrode, the first fin structure, and the second fin structure extend along a first direction and are substantially parallel to one another.

5. The integrated chip of claim 4, further comprising:
an isolation structure overlying the base region of the substrate and abutting the first and second fin structures on opposite sides of the gate structure, wherein a top surface of the gate electrode is disposed below a top surface of the isolation structure.

6. The integrated chip of claim 4, wherein lengths of the first and second fin structures are less than a length of the gate electrode.

7. The integrated chip of claim 1, further comprising:
a capacitor overlying the first fin structure, wherein a first electrode of the capacitor is electrically coupled to the first source/drain region and a second electrode of the capacitor is electrically coupled to a reference voltage; and
a read transistor comprising a gate electrode electrically coupled to the first source/drain region and the first electrode of the capacitor, wherein source/drain regions of the read transistor are coupled between a read bit line and a read write line.

8. The integrated chip of claim 7, wherein the second source/drain region is electrically coupled to a write bit line and the gate structure is coupled to a write word line.

9. An integrated chip, comprising:
a capacitor overlying a substrate and comprising a first electrode electrically coupled to a storage node; and
a first transistor disposed on the substrate, wherein the first transistor comprises a first fin structure, a second fin structure, a first source/drain region, a second source/drain region, and a gate structure, wherein the first and second fin structures extend upward from a base region of the substrate and are laterally offset from one another, wherein the gate structure is disposed between the first and second fin structures, wherein the first and second source/drain regions overlie a corresponding one of the first and second fin structures, wherein the first source/drain region is electrically coupled to the storage node.

10. The integrated chip of claim 9, further comprising:
a second transistor disposed on the substrate, wherein the second transistor comprises a gate electrode coupled to the storage node.

11. The integrated chip of claim 10, wherein a first length of a first channel region of the first transistor is greater than a second length of a second channel region of the second transistor.

12. The integrated chip of claim 11, wherein the second channel region of the second transistor extends continuously along a top surface of the substrate directly between a pair of source/drain regions of the second transistor, wherein the first channel region of the first transistor extends in vertical directions along sidewalls of the gate structure and in a horizontal direction along a bottom surface of the gate structure.

13. The integrated chip of claim 9, wherein the gate structure comprises a gate dielectric layer and a gate electrode, wherein the gate dielectric layer is spaced between the gate electrode and the first and second fin structures, wherein a top surface of the gate dielectric layer is vertically above a top surface of the gate electrode.

14. The integrated chip of claim 13, wherein tops of the first and second source/drain regions are aligned with the top surface of the gate dielectric layer.

15. The integrated chip of claim 13, further comprising:
an isolation structure over the base region of the substrate and on opposing sides of the first and second fin structures, wherein the isolation structure contacts a first sidewall of the first fin structure opposite a second sidewall of the first fin structure, wherein the second sidewall contacts the gate dielectric layer.

16. The integrated chip of claim 15, wherein a height of the isolation structure is greater than a height of the gate electrode.

17. A method for forming an integrated chip, comprising:
patterning a substrate to form a first fin structure and a second fin structure over a base region of the substrate;
forming a first source/drain region on the first fin structure and a second source/drain region on the second fin structure;
depositing a gate dielectric layer over the substrate and along sidewalls of the first and second fin structures; and
forming a gate electrode over the gate dielectric layer and laterally between the first and second fin structures.

18. The method of claim 17, wherein the first and second source/drain regions are formed before depositing the gate dielectric layer, wherein the gate dielectric layer extends along tops of the first and second source/drain regions.

19. The method of claim 17, further comprising:
forming an isolation structure over the base region of the substrate and on opposing sides of the first and second fin structures, wherein a top surface of the gate electrode is recessed below a top surface of the isolation structure.

20. The method of claim 19, wherein the first fin structure has a first sidewall opposite a second sidewall, wherein the gate dielectric layer directly contacts the first sidewall and wherein the isolation structure directly contacts the second sidewall.
